(19) United States
(12) Patent Application Publication
(10) Pub. No.: US 2020/0362455 A1
(43) Pub. Date: Nov. 19, 2020

(54) METHOD OF DIAMOND NUCLEATION AND STRUCTURE FORMED THEREOF

(71) Applicant: National Cheng Kung University, Tainan City (TW)

(72) Inventor: Yon-Hua TZENG, Tainan City (TW)

(73) Assignee: National Cheng Kung University

(21) Appl. No.: 16/705,528

(22) Filed: Dec. 6, 2019

Related U.S. Application Data
(60) Provisional application No. 62/846,767, filed on May 13, 2019.

(51) Int. Cl. C23C 16/27; C23C 16/513; C23C 16/06; C23C 28/00

(52) U.S. Cl. CPC C23C 16/276; C23C 16/513; B01J 23/72; C23C 28/343; C23C 28/32; C23C 16/06

(57) ABSTRACT

The present invention relates to a method of diamond nucleation, comprising the following steps: providing a substrate and forming a metal layer on the substrate, wherein the metal layer comprises a catalyst and a transitional metal, the catalyst is copper, nickel or a combination. thereof, and the transitional metal is tungsten, molybdenum or a combination thereof; providing a reaction chamber and disposing the substrate in the reaction chamber; providing a gas mixture in the reaction chamber, wherein the gas mixture includes a carbon-containing gas and hydrogen gas; causing the carbon-containing gas to react and form a graphene layer on the metal layer; and causing the graphene to react with the transitional metal and the carbon-containing gas to form diamond nuclei on the metal layer at a border between the graphene layer and the metal layer. The present invention also relates to a structure formed by the aforesaid method.

### CROSS REFERENCE TO RELATED APPLICATION

This application claims the benefit of filing date of U. S. Provisional Application Ser. No. 62/846,767, filed May 13, 2019 under 35 USC § 119(e)(1).

### BACKGROUND

### 1. Field of the Invention

The present invention relates to a method of diamond nucleation and a structure formed thereof. More particularly the present invention relates to a method of diamond nucleation induced by a metal layer containing a transitional metal and a catalyst for graphene synthesis and a structure formed thereof.

### 2. Description of Related Art

Diamond has excellent physical, chemical, optical, mechanical, and electrical properties. For example, diamond has high thermal conductivity coefficient, chemical inertness, biocompatibility, highest rigidity, high Young's modulus, low friction coefficient, wide energy gap, and broad optical transmission frequency-domain. Large single crystals can be grown from small diamond seeds for semiconductor, heat spreader, optical, mechanical and electrochemical applications. Nano-scale single crystal diamond particles are being used as drug vehicles. Polycrystalline. diamond plates and coatings preserve most of excellent properties of single crystal diamond and allow large-area diamond based and coated objects of a variety of shapes to be manufactured for practical applications. As a result, diamond has been widely used in industry in recent years.

When forming diamonds on non-diamond substrates, diamond seeding or mechanisms for the nucleation of diamond on non-diamond substrates must be achieved first. Diamond nuclei grow larger in size to fit application requirements. Since self-nucleation without needing to place diamond particles on a substrate simplifies diamond deposition processes, there are many studies dedicated to methods of diamond self-nucleation. However, under sub-atmospheric pressure and temperature below 1200C., diamond is thermodynamically metastable while graphite being stable. Formation of stable graphite is more favorable than metastable diamond. One kind of heterogeneous nucleation is bias-enhanced nucleation (BEN).

During bias-enhanced nucleation, a negative bias voltage with respect to the plasma is applied externally on substrates. Kinetic energy of positive ions accelerated by the biasing voltage for bombarding the substrate surface is applied to the growing diamond species, among them those favorable for diamond nucleation are preserved chemically while the rest are suppressed or etched away. This leads to an increasing number of diamond nuclei and enhanced diamond nucleation. However, uniform ion flux driven by biasing voltage on large and nonplanar surfaces is more difficult during bias-enhanced diamond nucleation processes. Due to electric field screening, bias-enhanced diamond nucleation also fails to penetrate to reach side wails of narrow grooves in substrates in order to enhance diamond nucleation on the sidewalls of grooves where the electric field perpendicular to the sidewall surface is weak. Although some related researches have reported that additional coating layers, such as an amorphous carbon layer, can also promote nucleation, the diamond nuclei formed usually are of low density and fail to distribute evenly for forming a smooth and continuous diamond film.

Nowadays, plasma enhanced chemical vapor deposition (CVD) and hot-filament chemical vapor deposition are common and well-developed methods for diamond synthesis. The precursors used are usually hydrocarbon materials, or carbon-containing materials with addition of different amounts of argon gas, hydrogen gas, oxygen. gas, and nitrogen gas, etc. When diamonds of different crystal orientations join to form a film, the film is known as a polycrystalline diamond film. For plasma enhanced CVD, diamond is formed by ionizing, exciting, and decomposing gas mixtures containing the aforesaid precursors using various types of energy sources, For hot-filament CVD, high-temperature of metal filament is applied to dissociate aforesaid precursors. In the following, only microwave plasma enhanced CVD will he described. Similar technology can be extended to different plasma sources and to hot filament assisted precursor dissociation.

In microwave plasma chemical vapor deposition (MPCVD), one or more reactive materials provided into reactors are first excited, dissociated, ionized and heated by microwave plasma. Ionization, decomposition, recombination, and chemical reactions of the reactive materials then occur. A solid film is then deposited on a diamond surface or a surface of a non-diamond substrate having diamond nuclei, However, until now, it is still rather difficult to deposit a continuous diamond film on substrates without diamond seeding and without negative biasing voltage using microwave plasma chemical vapor deposition.

Recently, U.S. Pat. No. 10,351,948 demonstrated the diamond nucleation without diamond seeds nor externally applied negative biasing to the substrate. Graphene was synthesized by thermal CVD on copper foils using copper as a catalyst. Graphene, especially monolayer graphene films are transferred from copper foils to the substrate on which diamond is to be formed. On the substrate surface, a layer of transitional metal including for example, tungsten and molybdenum is deposited before graphene is transferred to cover the metal surface. Under the plasma enhanced CVD conditions for diamond growth, graphene reacts with the plasma and the underneath tungsten metal to enhance formation of tungsten carbide and carbon sp3 bonds near edges and defects of graphene. These new structures promote addition of carbon atoms for forming diamond nuclei leading to formation of diamond nucleation and further growth into diamond films, This is the first time when diamond nucleation on non-diamond substrate without diamond seeds nor externally applied negative bias to the substrate was invented. The invention implies that by transferring quantum dots or exfoliated flakes of graphene and its derivatives such as graphene oxide and reduced graphene oxide to tungsten and transitional metal surfaces, diamond nucleation will occur without externally applied bias voltage nor diamond seeds.

Thermal CVD of graphene requires high temperature processes. The transfer of large-area graphene to cover large-area, especially nonplanar substrate surface is even more complicated. To transfer stacked graphene for multiple times is time consuming. Therefore, there is a need for inventing methods of diamond nucleation without requiring complicated and time-consuming processes of transferring graphene from one substrate favorable for graphene growth to the other substrate where diamond is to be fulfilled. The diamond nucleation process must be simple, inexpensive, compatible with industrial equipment for large-area and non-planar substrates.

### SUMMARY

The main object of the present invention is to provide a novel method of diamond nucleation and a structure formed thereof. In particular, the method provided by the present invention can form diamond nuclei on non-diamond substrates without diamond seeding and external bias voltage nor needing to transfer a graphene to the substrate on which diamond is to nucleate.

The method of the present invention comprises the following steps: providing a substrate and forming a metal layer on a surface of the substrate, wherein the metal layer comprises a catalyst and a transitional metal, the catalyst is copper, nickel or a combination thereof and the transitional metal is tungsten, molybdenum or a combination thereof; providing a reaction chamber and disposing the substrate with the metal layer formed thereon in the reaction chamber; providing a gas mixture in the reaction chamber, wherein the gas mixture includes a carbon-containing gas and hydrogen gas; causing the carbon-containing gas to react and form a graphene layer on a surface of the metal layer; and causing the graphene layer to react with the transitional metal and the gas mixture of the hydrogen gas and the carbon-containing gas to form diamond nuclei on the metal layer at a border along edges of the graphene layer and between the graphene layer and the metal layer.

A structure formed by the method of the preset invention comprises: a substrate; a metal layer disposed on the substrate, wherein the metal layer comprises a catalyst and a transitional metal, the catalyst is copper, nickel or a combination thereof, and the transitional metal is tungsten, molybdenum or a combination thereof; a graphene layer formed on the metal layer; and a plurality of diamond nuclei formed on the metal layer at a border between the graphene layer and the metal layer. Herein, the diamond nuclei are formed by reactions among the graphene layer, the transitional metal, and the plasma in the carbon-containing gas mixture,

Another structure formed by the method of the present invention comprises: a substrate; a metal layer disposed on the substrate, wherein the metal layer comprises a catalyst and a transitional metal, the catalyst is copper, nickel or a combination thereof, and the transitional metal is tungsten, molybdenum or a combination thereof, a graphene layer formed on the metal layer; and a diamond film formed by merging diamond islands grown from diamond nuclei formed on the metal layer at a border between the graphene layer and the metal layer.

Another structure formed by the method of the present invention comprises: a substrate; multiple metal layers disposed on the substrate, wherein the metal layers comprise alternately a catalyst layer and a transitional metal layer, the catalyst layer comprises copper, nickel or a combination thereof, and the transitional metal layer comprises tungsten, molybdenum or a combination thereof; a graphene layer formed by the assistance of the catalyst layer on the metal layers; and a diamond film formed on the metal layers at a border between the graphene layer and the metal layers.

Another structure formed by the method of the present invention comprises: a substrate; multiple layers of metal disposed on the substrate, wherein a first metal layer of the multiple layers is a transitional metal layer and overlayers on the first metal layer comprise alternately a catalyst layer and a buffer layer, the catalyst layer comprises copper, nickel or a combination thereof, and the buffer layer comprises silicon or metal through which carbon can diffuse through the buffer layer to the next catalyst layer; multiple graphene layers formed by the assistance of the catalyst layer on the transitional metal layer; and a diamond film formed on the transitional metal layer at a border between the graphene layers and the transitional metal layer,

### DETAILED DESCRIPTION

The method of the present invention comprises the following steps: providing a substrate and forming a metal layer, wherein the metal layer comprises a catalyst and a transitional metal, or a stack of multiple metal layers of materials including a catalyst and a transitional metal on a surface of the substrate the catalyst is copper, nickel or a combination thereof, and the transitional metal is tungsten, molybdenum or a combination thereof; providing a reaction chamber and disposing the substrate with the metal layer or metal layers formed thereon in the reaction chamber; providing a gas mixture in the reaction chamber, wherein the gas mixture includes a carbon-containing gas and hydrogen gas is added at the beginning or at later time; causing the carbon-containing gas to react and form a graphene layer on a surface of the metal layer or multiple metal layers; and causing the graphene layer to react with the transitional metal and the gas mixture of the carbon-containing gas and the hydrogen gas to form diamond nuclei on the metal layer or metal layers at a border between a graphene layer or multiple graphene layers and the metal layer or metal layers. In the method of the present invention, a graphene layer reacts with the transitional metal to form sp3 bonded structures (also called as a graphene-metal layer), on which plasma in the gas mixture of the carbon-containing gas and the hydrogen gas reacts to form diamond nuclei on the graphene-metal layer. In particular, the sp3 bonded structure between the graphene layer and the transitional metal is formed at the edge of graphene islands of the graphene layer. In the method of the present invention, diamond seeds are not disposed on the substrate or on the graphene layer, and no negative bias is externally applied to the substrate. In addition, there is no need to transfer separately synthesized graphene onto the metal layer or metal layers comprising the catalyst and the transitional metal.

The method provided by the present invention can produce high purity diamond nuclei, which allows further growth by different plasma chemistry to form discrete ultra-nanocrystalline diamond particles, discrete nanocrystalline diamond particles, discrete microcrystalline diamond particles, ultra-nanocrystalline diamond coatings, nanocrystalline diamond coatings, microcrystalline diamond coatings or a variety of 3-dimensional diamond objects.

After carrying out the method of the present invention, a structure is obtained, which comprises: a substrate; a metal layer disposed on the substrate, wherein the metal layer comprises a catalyst for forming graphene and a transitional metal, the catalyst is copper, nickel or a combination thereof, and the transitional metal is tungsten, molybdenum or a combination thereof; a graphene layer formed on the metal layer; and a plurality of diamond nuclei formed on the metal layer at a border between the graphene layer and the metal layer or a diamond film formed by merging of diamond islands or diamond particles grown from diamond nuclei formed on the metal layer at a border between the graphene layer and the metal layer. In particular, the diamond nuclei or the diamond film is formed on the graphene-metal layer.

In the present invention, the graphene can be a continuous graphene film or plural graphene islands.

In the present invention, the catalyst contained in the metal layer can be any catalyst for graphene formation, such as copper, nickel or a combination thereof. Herein, the catalyst assists catalytic reaction for forming graphene in-situ, and the graph=is grown in areas where the catalyst is present and exposed to active carbon species. In one embodiment of the present invention, the catalyst is copper.

In the present invention, the transitional metal contained in the metal layer can be any carbide forming transitional metal such as tungsten, molybdenum or a combination thereof. In one embodiment of the present invention, the transitional metal is tungsten. Furthermore, in one embodiment of the present invention, the metal layer is a tungsten-copper film.

In the present invention, the metal layer containing the catalyst and the transitional metal can be formed by methods commonly used in the art, such as sputtering, thermal evaporation, electron evaporation, solution deposition, insertion of a layer of multiple particles of transitional metal into a catalyst layer, or insertion of a layer of multiple particles of catalyst for grapheme formation into a transitional metal layer.

In the present invention, the transitional metal and the catalyst can be deposited simultaneously on the substrate to form a single layer comprising the catalyst and the transitional metal; the transitional metal and the catalyst can also be deposited sequentially and alternately on the substrate to form multiple-layer metal films containing both the transitional metal and the catalyst; or the transitional metal and the catalyst are deposited in adjacent areas with lateral boundaries on the substrate. To achieve lateral boundaries, transitional metal, such as tungsten, particles can also be embedded in a layer of catalyst such as copper, or catalyst, such as copper, particles can be embedded in a layer of transitional metal such as tungsten, Furthermore, to achieve lateral boundaries, lithographic technique such as chemical etching or physical milling can be applied to etch selected areas of a top layer of metal to expose the second layer of metal. In one embodiment of the present invention, the metal layer comprises copper and tungsten, and thus the metal layer is a tungsten-copper film. In another embodiment of the present invention, the metal layer is a co-sputtered tungsten-copper film. In further another embodiment of the present invention, the metal layer is co-sputtered tungsten-copper film formed by radio frequency magnetron co-sputtering using a sputtering target containing both tungsten and copper. Herein, the ratio of contents of the tungsten to the copper in the sputtering target may be respectively in a range from 0.1% to 99.9%, in a range from 1% to 99%, in a range from 20% to 80% or in a range from 40% to 60%. In one embodiment of the present invention, the sputtering target contains 60% tungsten and 40% copper, However, the present invention is not limited thereto.

In the present invention, graphene reacts with tungsten to create favorable sp3 structures for promoting diamond nucleation directly on the tungsten-copper film. There is no need for transferring graphene from a different substrate such as a copper foil to a substrate coated with tungsten for diamond nucleation. Transfer-free graphene films or graphene islands are formed on the tungsten-copper coated substrate for diamond nucleation directly. Although plasma-graphene-tungsten interactions leading to diamond nucleation is similar to U.S. Pat. No. 10,351,948, the present invention for diamond nucleation does not require the transfer and stacking of pre-synthesized graphene films, Since tungsten-copper films can be coated on a wide variety of substrates including metals and ceramics which can withstand diamond growth environments, and can be coated on a wide variety of 3-dimensional objects including side-walls of trenches, internal walls of a tubing, and even interior surfaces of a porous materials, the range of usefulness of a transfer-free graphene based diamond nucleation is a major progress in diamond technology. The present invention is therefore innovative, better and more economic than the diamond nucleation method based on transferred graphene.

In the present invention, the formation of graphene can be a thermal chemical vapor deposition (CVD) process or a plasma enhanced CVD process which are commonly known by technical persons in the field of art. In one embodiment of the present invention, plasma can be formed in the reaction chamber and the graphene layer can be formed by plasma enhanced CVD. In another embodiment of the present invention, the formation of graphene is by thermal CVD without plasma assistance.

In the present invention, the formation of diamond nuclei can be a plasma enhanced CVD process, a hot-filament based thermal CVD process or other methods commonly known in the art of diamond CVD. In one embodiment of the present invention, plasma can be formed in the reaction. chamber and the diamond nuclei can be formed by plasma enhanced CVD.

In the present invention, the method may further comprise a step of: causing the gas mixture of the carbon-containing gas and the hydrogen gas to react and form a diamond film from the diamond nuclei. Herein, the formation of the diamond film can be a plasma enhanced CVD process, a hot-filament based thermal CVD process or other methods commonly known in the art of diamond CVD. In one embodiment of the present invention, the diamond film can be formed by plasma enhanced CVD.

In the present invention, the plasma enhanced CVD chemistry for graphene synthesis can be the same as or different from that for diamond nucleation and diamond growth. In one embodiment of the present invention, an optimized graphene synthesis commonly known in the field of art is applied and the CVD condition for the formation of the graphene is changed to an optimized diamond nucleation process commonly known in the field of art; and then, the subsequent. growth of diamond nuclei to form diamond films will need further modification of the CVD process. In another embodiment of the present invention, the conditions for the formation of the graphene, the diamond nuclei and the diamond film are the same. These processes are all commonly known and will not be described in more details here.

In the present invention, the graphene, the diamond nuclei or the diamond film is firmed by microwave plasma CVD. Herein, the microwave power can be adjusted according to different microwave frequencies and reactor sizes.

In addition, the purity and quality of the synthesized diamonds can be increased by controlling the flow of the gas mixture, Specifically, the flow of the gas mixture is controlled to prevent carbon soot formation from excessive carbon-containing gas in the reaction chamber, In the present invention, the total flow of the gas mixture may be adjusted according to the size of the reaction chamber, the microwave power, the deposition pressure, and the content of the carbon-containing gas in the gas mixture. More specifically, the total flow of the gas mixture is adjusted to optimize the residence time of the reactive gas in the reaction chamber. This assures the amount of carbon in the reaction chamber is optimized for graphene synthesis and diamond nucleation but less than the amount required by carbon soot formation by gas-phase synthesis. This prevents the plasma from being unstable because the plasma will be un-stabilized by carbon soot formation by gas-phase synthesis. Thereby, the quality of diamond nucleation is increased.

In the preset invention, the microwave power can be in a range from 100 W to 100000 W, depending on the size of the CVD reactor. For example, the microwave power can be in a range from 2000 W to 8000 W, 2000 W to 6000 W, 3000 W to 5000 W, 3000 W to 4000 W, or 4000 W to 5000 W. The deposition pressure (pressure of the gas mixture) can be in a range from 1 Torr to 1000 Torr. For example, the deposition pressure can be in a range from 20 Torr to 300 Torr, 2.0 Ton to 200 Ton, 20 Torr to 100 Ton, 30 Ton to 80 MIT, 40 Ton to 70 Ton, 50 Ton to 60 Torr. The substrate temperature can be in a range from 400° C. to 1200° C. For example, the substrate temperature can be in a range from 400° C. to 1000° C., 500° C. to 1000° C., 500° C. to 900° C., 600° C. to 900° C., 600° C. to 800° C., 650° C. to 900° C., or 650° C., to 800°C. The total flow of the gas mixture in the reaction chamber of 50 liters volume can be in a range from 1 sccm to 3000 sccm. For example, the total gas flow can be in a range from 1 sccm to 2500 sccm, 1 sccm to 2000 sccm, 1 sccm to 1000 sccm, 1 sccm to 800 sccm, 1 sccm to 700 sccm, 1 sccm to 600 sccm, or 1 sccm to 500 sccm. When the condition for the graphene formation, the diamond nucleation or the diamond film formation is within the aforesaid range, diamonds having high purity and high-quality can be synthesized.

In the present invention, the gas mixture is not particularly limited and may be any gas mixture commonly used in the CVD system for graphene formation and any gas mixture commonly used for diamond formation in the art, The carbon-containing gas of the gas mixture is also not particularly limited and may be any carbon-containing gases commonly used in the CVD system in the art. In the present invention, the carbon-containing gas can be a hydrocarbon gas, such as methane, acetylene, ethylene, and so on. The carbon containing gases can also be produced in-situ by reactions between a solid carbons deposited with hydrogen or hydrogen plasma. In one embodiment of the present invention, the carbon-containing gas is methane.

In the present invention, the volume percent of the carbon-containing gas in the gas mixture is not particularly limited. For example, the volume percent of the carbon-containing gas in the gas mixture can be in a range from 0.05% to 99.9%. In other embodiments, the volume percent can be in a range from 0.05 to 50%, 0.05% to 40%, 0.05% to 30%, 0.1% to 30%, 0.1% to 20%, or 0.1% to 10%, Nevertheless, the person having ordinary skill in the art may adjust the content of the carbon-containing gas in the gas mixture according to different densities of diamond nucleation desired,

In the present invention, the gas mixture may further comprise other gases such as argon. In one embodiment of the present invention, the gas mixture may further comprise hydrogen gas, and the volume percent of the hydrogen gas in the gas mixture is optimized under specific reaction conditions and not particularly limited. For example, a volume ratio of hydrogen to the carbon-containing gas in the gas mixture is in a range from 1 to 200. In other embodiment, the volume ratio can be in a range from 1 to 180, 1 to 160, 5 to 160, 5 to 140, 10 to 140, 10 to 100, 10 to 100, 20 to 80, 30 to 70, 40 to 60, 60 to 40, 70 to 30, 80 to 20, 90 to 10, 95 to 5, 97 to 3, 98 to 2.99 to 1, 99.5 to 0.5. In another embodiment of the present invention, the gas mixture may further comprise argon gas, and the volume percent of the argon gas in the gas mixture is not particularly limited. For example, a volume ratio of argon to hydrogen in the gas mixture is in a range from 0 to 200. In other embodiment, the volume ratio can be in a range from 0 to 180, 0 to 160, 5 to 160, 5 to 140, 10 to 140, 10 to 100, or 10 to 100. For the growth of ultrananocrystalline diamond films, hydrogen can be fully replaced by argon.

In the present invention, further growth and joining of the diamond nuclei forms diamond films made of different sizes of diamond grains and oriented in different orientation. The ultra-nanocrystalline diamond film contains diamond grains of 2 nm to 10 nm in size. The nanocrystalline diamond film contains diamond grains of 10 nm to 100 nm in size. The microcrystalline diamond film contains diamond grains of 100 nm to multiple micrometers in size.

Different diamond growth conditions are applied and are commonly known by technical persons in the field of art of diamond CVD. For example, for the formation of the diamond film containing diamond grain sizes of 100 nm or larger, the carbon-containing gas (for example, methane) is diluted by mainly hydrogen with methane to hydrogen gas ratio being 0.1% to 90%, 0.5% to 15%, more preferably 0.7% to 12%, and most preferably 1% to 3%. Argon gas can be added but is optional with methane to argon gas ratio being 0.1% to 99%, 0.5% to 99%, more preferably 0.5% to 20% and most preferably 1% to 10%. Additional hydrogen can be added to stabilize the process plasma and help etch. non-diamond carbon phases. In addition, for the formation of the diamond film containing diamond grain sizes of 10 nm to 100 nm, the hydrocarbon gas may be diluted by both argon and hydrogen. The larger the diamond grain sizes are desired, the more hydrogen is added.

In the present invention, the substrate may be any desired object for diamond crystal deposition. The substrate is not particularly limited. As long as the thin film containing the transitional metal and the catalyst can. adhere well to the substrate and the substrate can withhold the temperature and chemical environments in which diamond nucleation processes occur, it is included.

In the present invention, the substrate can be a silicon substrate, a silicon dioxide substrate, a silicon wafer, a copper substrate, a nickel substrate, a tungsten substrate, a molybdenum substrate, a titanium substrate, or a metal or ceramic substrate coated by copper, nickel, tungsten, molybdenum, titanium, silicon or a combination thereof.

A metallic substrate (for example, a transitional metal substrate such as a molybdenum substrate or a tungsten substrate) or a metal-ceramic composite substrate can also serve as the substrate of the present invention. The substrate which has high carbon solubility and is difficult for direct diamond nucleation becomes a suitable substrate after having been coated with the metal layer containing the transitional metal and the catalyst (for example, the tungsten-copper film). The metal layer containing the transitional metal and the catalyst (for example, the tungsten-copper film) can further serve as an adhesion promoter for the diamond film to adhere to the substrate, on which the diamond film has difficulty in adhering due to lacking bonding strength and the large difference in coefficients of thermal expansion of the diamond film and the substrate. This will broadly extend the substrate material on which the diamond film can be coated for enhancing mechanical, chemical, thermal properties of practical applications. Machine tools are examples of mechanical applications. Corrosion resistant coating and electrochemical electrodes are examples of chemical applications. Heat spreader for high-power devices is an example of thermal applications.

For the tungsten substrate or the substrate which has already been coated with tungsten, a copper layer deposited on the tungsten surface or partially covering the tungsten surface will induce transfer free graphene growth on the copper layer and the interface between the copper layer and the tungsten surface using copper as the catalyst. By the method of this invention, reactions of graphene formed by this method under the diamond CVD environments in the presence of atomic hydrogen and carbon containing radicals and the reactions of graphene with the transitional metal substrates will result in diamond nucleation.

For the copper substrate or the substrate which has already been coated with copper, a tungsten layer is deposited to cover all or part of the copper surface. When the copper surface coated with the tungsten layer is exposed to the diamond CVD condition (for example, microwave plasma in 1% methane diluted by hydrogen, but the present invention is not limited thereto), carbon species will diffuse to the copper-tungsten interface through tungsten and form graphene by the aid of the copper catalyst. Copper can diffuse to the surface of the transitional metal to form graphene. When the tungsten layer is so thin that atomic hydrogen and carbon containing radicals can diffuse through tungsten which forms multiple pinholes and cracks, diamond nucleation occurs at graphene along the edges of tungsten pinholes and cracks and at the interface between the tungsten layer and the copper surface. After further growth of the diamond nuclei, the diamond film can be grown on the copper surface.

Other objects, advantages, and novel features of the present invention will become more apparent from the. following detailed description when taken in conjunction with the accompanying drawings.

### BRIEF DESCRIPTION OF THE DRAWINGS

FIG. 1 is a schematic diagram showing a structure including a substrate, a tungsten-copper layer, a graphene layer, and diamond nuclei according to Embodiment 1 of the present invention.

FIG. 2 shows a Raman spectrum of diamond crystals formed in Embodiment 1 of the present invention.

FIG. 3 is an optical microscope image of diamond crystals formed in Embodiment 1 of the present invention.

FIG. 4 shows a Raman spectrum of graphene in area of the substrate where the surface is not covered by diamond nuclei in Embodiment 1 of the present invention.

FIG. 5 shows a Raman spectrum of diamond crystals formed in Embodiment 2 of the present invention.

### DETAILED DESCRIPTION OF EMBODIMENT

The following embodiments when read with the accompanying drawings are made to clearly exhibit the above-mentioned and other technical contents, features and/or effects of the present disclosure. Through the exposition by means of the specific embodiments, people would further understand the technical means and effects the present disclosure adopts to achieve the above-indicated objectives. Moreover, as the contents disclosed herein should be readily understood and can be implemented by a person skilled in the art, all equivalent changes or modifications which do not depart from the concept of the present disclosure should be encompassed by the appended claims.

Furthermore, when a value is in a range from a first value to a second value, the value can be the first value, the second value, or another value between the first value and the second value.

### Embodiment 1

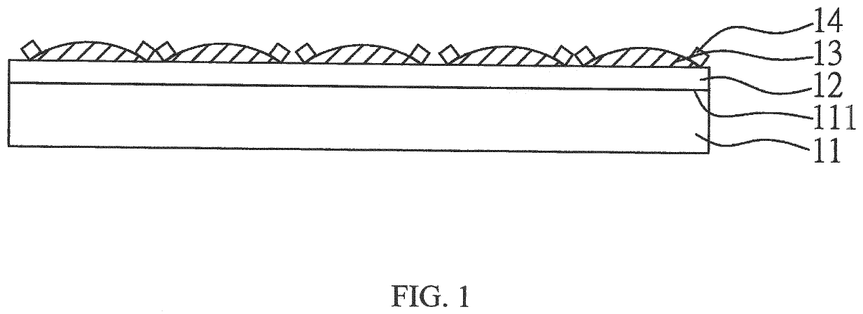

FIG. 1 is a schematic diagram showing a structure of the present embodiment.

In the present embodiment, a substrate 11 is provided, which is a silicon substrate. A metal layer 12, which is a tungsten-copper film, is co-sputtered on a surface 111 of the substrate 11. In the present embodiment, the metal layer 12 (i.e. the tungsten copper film) is co-sputtered on the substrate 11 (i.e. the silicon substrate) in an argon environment by RF magnetron sputtering. The sputtering power is 90 W at a gas pressure of 2×10⁻² ton, under 30 sccm flow of argon. The sputtering process lasts for 15 mins,

Next, the substrate 11 coated with the metal layer 12 (i.e. the to film) is placed into a reaction chamber (not shown in the figure), and a gas mixture containing methane gas, hydrogen gas, and argon gas is provided into the reaction chamber to carry out a plasma enhanced chemical vapor deposition process. A graphene layer or discrete graphene island 13 is formed on the metal layer 12 (i.e. the tungsten-copper film) by the copper catalyst and the plasma enhanced CVD reacts with both graphene and tungsten to produce sp3 bond structure which is favorable for diamond nucleation.

In the reaction chamber, the gas mixture containing 1% methane diluted by the hydrogen gas and the argon gas reacts to form a plurality of diamond nuclei 14 on a surface of the metal layer 12 (i.e. the tungsten-copper film) where the graphene layer 13 is formed in-situ before diamond nuclei are formed. Specifically, a total flow of the gas mixture of 5 sccm of the methane gas and 500 sccm of the hydrogen gas in the reaction chamber of 50 liters volume is reacted for 2 hr under conditions such as a microwave power of 4000 W, a deposition pressure of 55 Torr, and a substrate temperature of 710°C.

In the present embodiment, no diamond seed is disposed on the substrate 11 nor on the metal layer 12 (i.e. the tungsten-copper film). Both the substrate 11 and the metal layer 12 (i,e. the tungsten-copper film) are not processed by bias-enhanced diamond nucleation.

After the aforesaid process, as shown in FIG. 1, the structure is formed by synthesizing diamond nuclei 14 through reactions by the Diamond CVD plasma with the graphene layer 13 and the transitional metal predominantly along edges of in-situ formed graphene layer 13 on the substrate 11 coated with the metal layer 12 (i.e. the tungsten-copper film). More specifically, the structure of the present embodiment comprises: a substrate 11; a metal layer 12 (i.e. the tungsten-copper film) disposed on the substrate 11; a graphene layer 13 formed on the metal layer 12; and a plurality of diamond nuclei 14 formed on the metal layer 12 at a border between graphene layer 13 and the metal layer 12.

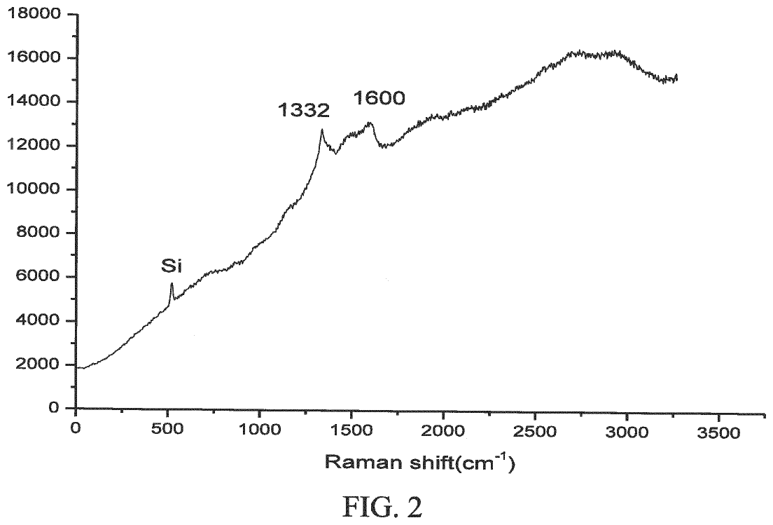

FIG. 2 shows a Raman spectrum (excited by a 532 μm laser) of diamond crystals formed in the present embodiment. Specifically, diamond crystals are formed on a graphene-tungsten-copper layer, on which graphene is formed with copper as a catalyst before diamond nuclei are fanned.

As shown in FIG. 2, the signal intensity of the diamond Raman peak at 1332 cm⁻¹ is clear and sharp. Besides the diamond peak, G-band (around 1600 cm⁻¹), D-band between the diamond peak and the G-band (around 1450 cm⁻¹), and 2-D band (around 2700 cm⁴) originating from graphene are also clearly displayed. The silicon peak comes from the silicon substrate. This result demonstrates that diamond crystals have been formed on the graphene-tungsten-copper layer.

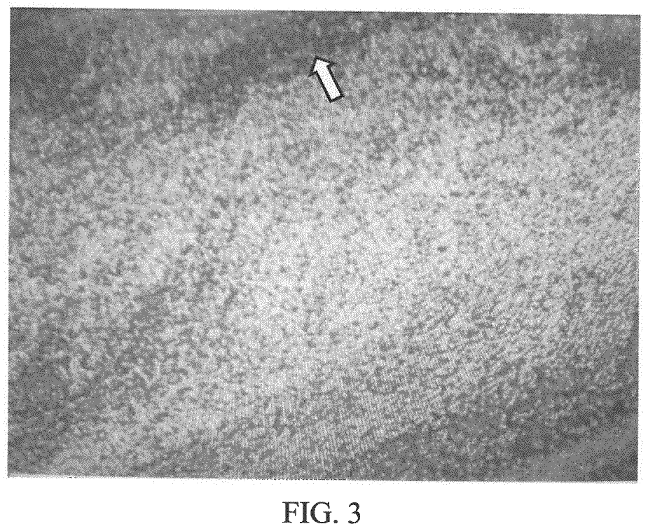

FIG. 3 is an optical microscope image (×1000) of diamond crystals formed in the present embodiment. As shown in FIG. 3, individual diamond crystals are clearly seen. The density of diamond crystals is so high that a continuous diamond film can be formed after those diamond crystals grow larger both vertically and laterally. A silicon substrate coated with tungsten-copper by RF magnetron co-sputter from a tungsten target with 40% of the surface of a tungsten target having been covered by a copper foil. Tungsten atoms and copper atoms are knocked out of the target by energetic ions and diffuse and become mixed when they arrive at the substrate to deposit a thin film containing both tungsten and copper. The copper is used as a catalyst for forming graphene by-plasma enhanced CVD in 1% methane gas diluted by hydrogen. Graphene reacts with the plasma and the tungsten for promoting the formation of sp3 bonded graphene edges and defective sites, where carbon containing radicals are attached to form diamond nuclei.

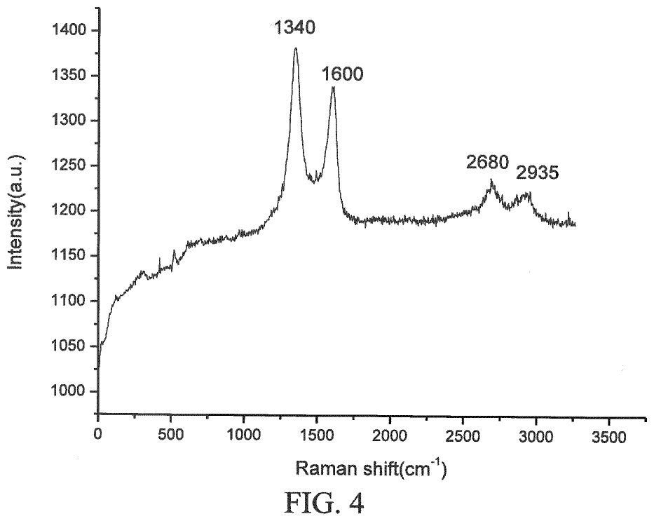

FIG. 4 shows a Raman spectrum of exposed graphene which is formed on the tungsten-copper film in the present embodiment. The strong D-band at 1340 cm⁻¹, fig-band at 1600 cm⁻¹, and 2-D band at 2680 cm⁻¹ are clearly displayed and characteristic of graphene islands with abundant edges. It demonstrates that copper in the tungsten-copper film serves well as a catalyst to form graphene on the tungsten-copper film in-situ under plasma excitation in a gas mixture of 1% methane diluted by hydrogen, and synthesis of a continuous diamond film is then induced. In another word, the graphene synthesis, diamond nucleation, and diamond growth processes are integrated in one process without changing the plasma chemistry. However, this does not limit the further optimization of the integrated diamond nucleation and growth process for the fabrication of diamond films of different grain sizes. Ultrananocrystalline diamond films with grain sizes of few to several nanometers in size need the process gas mixture to he diluted mainly by argon gas so as to promote secondary nucleation, Microcrystalline diamond films with grain sizes of one hundred nanometers to multiple micrometers require the process gas mixture to be diluted by abundant hydrogen gas to suppress secondary nucleation and to enhance the diamond growth rate. Nanocrystalline diamond films need gas mixture between those for ultra-nanocrystalline diamond films and for microcrystalline diamond films.

### Embodiment 2

The process and the structure of the present embodiment are similar to those of Embodiment 1, except for the conditions of the plasma enhanced CVD.

In the present embodiment, the diamond. films are grown at a higher substrate temperature of 850° C. at 65 Torr gas pressure in 1% methane diluted by hydrogen under 4000 W microwave excitation for two hours.

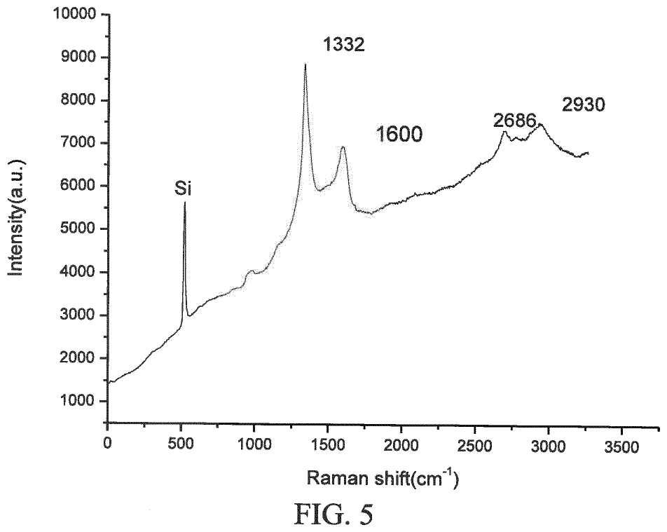

FIG. 5 shows a Raman spectrum of diamond crystals formed in the present embodiment. The signal strength of diamond Raman peaks at 1332 cm⁻¹ shown in FIG. 5 is much stronger than that in FIG. 2. This is consistent with commonly known diamond CVD art. In the Raman spectrum, the signal strength of the D-band (at around 1450 cm⁻¹) from dis-ordered carbon phase is much weaker than that in FIG. 2. The G-hand (at around 1600 cm) and the 2-D band (at around 2686 cm⁻¹) are clear indicating better quality of graphene having been formed on the tungsten-copper thin film at a high substrate temperature of 850° C.

Although the present invention has been explained in relation to its preferred embodiment, it is to be understood that many other possible modifications and variations can be made without departing from the spirit and scope of the invention as hereinafter claimed.

What is claimed is:

1. A method of diamond nucleation, comprising the following steps:
providing a substrate and forming a metal layer on a surface of the substrate, wherein the metal layer comprises a catalyst and a transitional metal, the catalyst is copper, nickel or a combination thereof, and the transitional metal is tungsten, molybdenum or a combination thereof;
providing a reaction chamber and disposing the substrate with the metal layer formed thereon in the reaction chamber;
providing a gas mixture in the reaction chamber, wherein the gas mixture includes a carbon-containing gas and hydrogen gas;
causing the carbon-containing gas to react and form a graphene layer on a surface of the metal layer; and
causing the graphene layer to react with the transitional metal and the gas mixture of the hydrogen gas and the carbon-containing gas to form diamond nuclei on the metal layer at a border between the graphene layer and the metal layer.

2. The method as claimed in claim 1, wherein no diamond seed is disposed on the substrate nor on the graphene layer.

3. The method as claimed in claim 1, wherein no negative bias is externally applied to the substrate.

4. The method as claimed in claim 1, wherein plasma is formed in the reaction chamber and the graphene layer is formed by plasma enhanced. chemical vapor deposition.

5. The method as claimed in claim 1, wherein plasma is formed in the reaction chamber and the diamond nuclei are formed by plasma enhanced chemical vapor deposition.

6. The method as claimed in claim 1, further comprising a step of causing the gas mixture of the hydrogen gas and the carbon-containing gas to react and form a diamond film from the diamond nuclei,

7. The method as claimed in claim 1, wherein the carbon-containing gas is a hydrocarbon gas.

8. The method as claimed in claim 7, wherein the hydrocarbon gas is methane.

9. The method as claimed in claim 1, wherein the gas mixture farther includes argon.

10. The method as claimed in claim 1, wherein the metal layer is a single layer comprising the catalyst and the transitional metal.

11. The method as claimed in claim 1, wherein the catalyst is copper.

12. The method as claimed in claim 1, wherein the transitional metal is tungsten.

13. The method as claimed in claim 1, wherein the substrate is a silicon substrate, a silicon dioxide substrate, a silicon wafer, a copper substrate, a nickel substrate, a tungsten substrate, a molybdenum substrate, a titanium substrate, or a metal or ceramic substrate coated by copper, nickel, tungsten, molybdenum, titanium, silicon or a combination thereof.

14. A structure formed by the method as claimed in claim 1 comprising:
a substrate;
a metal layer disposed on the substrate, wherein the metal layer comprises a catalyst and a transitional metal, the catalyst is copper, nickel or a combination thereof, and the transitional metal is tungsten, molybdenum or a combination thereof;
a graphene layer formed on the metal layer; and
a plurality of diamond nuclei formed on the metal layer at a border between the graphene layer and the metal layer.

15. The structure as claimed in claim 14, wherein the catalyst is copper.

16. The structure as claimed in claim 14, wherein the transitional metal is tungsten.

17. A structure formed by the method as claimed in claim 1 comprising:
a substrate;
a metal layer disposed on the substrate, wherein the metal layer comprises a catalyst and a transitional metal, the catalyst is copper, nickel or a combination thereof, and the transitional metal is tungsten, molybdenum or a combination thereof,
a graphene layer formed on the metal layer; and
a diamond film formed by merging diamond islands grown from diamond nuclei formed on the metal layer at a border between the graphene layer and the metal layer.

18. The structure as claimed in claim 17, wherein the catalyst is copper.

19. The structure as claimed in claim 17, wherein the transitional metal is tungsten.
